(19) United States
(12) Patent Application Publication
(10) Pub. No.: US 2012/0302685 A1
(43) Pub. Date: Nov. 29, 2012

(54) MOISTURE BARRIER POTTING COMPOUND

(75) Inventors: Samuel Ward, Toledo, OH (US); Haewon L. Uhm, Ann Arbor, MI (US)

(73) Assignee: ADCO PRODUCTS, INC., Michigan Center, MI (US)

(21) Appl. No.: 13/575,876

(22) PCT Filed: Dec. 14, 2010
(86) PCT No.: PCT/US10/60297

§ 371 Date: Jul. 27, 2012

Related U.S. Application Data
(60) Provisional application No. 61/300,595, filed on Feb. 2, 2010.

(51) Int. Cl. C08L 23/20; H05K 7/02; H01L 31/0203; C08K 5/544

(52) U.S. Cl. 524/262; 361/752; 136/259

(57) ABSTRACT

A moisture barrier potting composition includes an olefinic polymer, a polyethylene wax, a silane, an antioxidant, and a filler. These components are balanced to produce a potting compound having desirable properties including Moisture Vapor Transmission Rate (MVTR), viscosity, temperature of application, and no sag at use temperatures. The moisture barrier potting composition may be employed with any solid state device including wire and junction box sealants in solar modules.

### RELATED APPLICATION

This application claims the benefit of U.S. Provisional Application No. 61/300,595, filed Feb. 2, 2010, the entire contents of which are incorporated herein by reference.

### FIELD OF INVENTION

The present invention relates to a moisture barrier potting compound, and more particularly a moisture barrier potting compound for use in solar applications, solid state meters, and other applications with water sensitive components.

### BACKGROUND

The statements in this section merely provide background information related to the present disclosure and may or may not constitute prior art. In many electrical devices, for example solid state devices such as meter readers, and photovoltaic devices or solar modules, various physical factors can impact the performance of the electrical devices. The particular physical factors and their intensity can vary dramatically for a given application. For example, in solid state devices such as in-ground water meter readers, moisture penetration is a constant issue since the device is buried below the frost line. In the case of solar modules located outside on a roofing structure or frame, the physical factors include hail impact, wind and snow loads, and moisture invasion. Moisture invasion in solid state devices is particularly problematic since the moisture may corrode metal contacts and components within the solid state device.

One solution is to use a potting compound to cover or seal the solid state device. Potting compounds protect the solid state devices against moisture, chemical, and particulate penetration. However, there is a constant desire to improve the characteristics of the potting compound, in terms of moisture barrier protection, while still providing a compound having a viscosity that allows the compound to adequately flow to cover or seal the solid state device without undue heating of the compound.

### SUMMARY

The present invention provides a moisture barrier potting composition. The composition includes an olefinic polymer, a wax, a silane, an antioxidant, and a filler. These components are balanced to produce a potting compound having desirable properties including Moisture Vapor Transmission Rate (MVTR), flow, temperature of application, and hardness. The moisture barrier potting composition may be employed with any solid state device including wire and junction box sealants in solar modules.

In one example of the moisture barrier potting composition, the olefinic polymer includes one of polyisobutylene, polybutene, amorphous butene or propene enriched polyethylene, or combinations thereof.

In another example of the moisture barrier potting composition, the wax is a polyethylene wax. The wax can have a softening or melting point between about 50° C. and 200° C.

In yet another example of the moisture barrier potting composition, the antioxidant includes Tetrakis [methylene(3,5-di-tert-butylhydroxyhydrocinnanamte)]methane.

In yet another example of the moisture barrier potting composition, the silane includes 3-(2-aminoethyl)-aminopropyltrimethoxysilane.

In yet another example of the moisture barrier potting composition, the filler includes at least one of titanium dioxide, calcium carbonate, fumed silica, and carbon black.

In yet another example of the moisture barrier potting composition, the composition has an MVTR of less than about 0.3 g/m² per 24 hours.

Further features, advantages, and areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way. The components in the figures are not necessarily to scale, emphasis instead being placed upon illustrating the principles of the invention. In the drawings:

FIG. 1 is a side cross sectional view of a portion of an exemplary solar module having a potting compound composition according to the principles of the present invention;

FIG. 2 is a side cross-sectional view of a another exemplary solar module having a potting compound composition according to the principles of the present invention;

FIG. 3 is a side view of an exemplary solid state device;

FIG. 4 is a top view of the exemplary solid state device;

FIG. 5 is a side cross sectional view of the exemplary solid state device having a potting compound composition according to the principles of the present invention; and

FIG. 6 is a side view of a solid state circuit board coated in the potting compound composition according to the principles of the present invention.

### DETAILED DESCRIPTION

The following description is merely exemplary in nature and is not intended to limit the present disclosure, application, or uses.

With reference to FIG. 1, an exemplary solar module having a moisture barrier potting compound according to the principles of the present invention is generally indicated by reference number 10. The solar module 10 may take various forms without departing from the scope of the present invention and generally includes a plurality of photovoltaic cells 12 located within a chamber 13 defined by a first substrate 14 and a second substrate 16. It should be appreciated that any number of photovoltaic cells 12 may be employed in the solar module 10.

The photovoltaic cells 12 are operable to generate an electrical current from sunlight striking the photovoltaic cells 12. Accordingly, the photovoltaic cells 12 may take various forms without departing from the scope of the present invention. For example, the photovoltaic cells 12 may be a thin film cell with a layer of cadmium telluride (Cd—Te), amorphous silicon, or copper-indium-diselenide (CuInSe₂). Alternatively, the photovoltaic cells 12 may be a crystalline silicon wafer embedded in a laminating film or gallium arsenide deposited on germanium or another substrate. Other types of photovoltaic cells 12 that may be employed include organic semiconductor cells having conjugate polymers as well as dye-sensitized metal oxides including wet metal oxides and solid metal oxides. The photovoltaic cells 12 may be either rigid or flexible. The photovoltaic cells 12 are linked either in series or in parallel or combinations thereof. The current generated by the photovoltaic cells 12 are communicated via bus bars or other conductive materials or layers 18 to wires or lead lines 20 that exit the solar module 10 via an opening 22 in the second substrate 16. The lead lines 20 communicate with a junction box 24 in order to distribute the electrical current generated by the solar module 10 to a power circuit.

The first substrate 14, or front panel, is formed from a material operable to allow wavelengths of sunlight to pass therethrough. For example, the first substrate 14 is glass or a plastic film such as polyvinylfluoride. The second substrate 16, or back panel, is selected to provide additional strength to the solar module 10. For example, the second substrate 16 is a plastic such as fluorinated ethylene-propylene copolymer (FEP), poly(ethylene-co-tetrafluoroethylene) (ETFE), polyvinylidene fluoride (PVDF), polyvinyl fluoride (PVF), poly(tetrafluoroethylene) (PTFE) and combinations of these with other polymeric materials.

The photovoltaic cells 12 are encapsulated by a laminate layer 26 that is, for example cross-linkable ethylene vinyl acetate (EVA). However, it should be appreciated that other laminates or encapsulants may be employed without departing from the scope of the present invention. The laminate layer 26 is used to partially encapsulate the photovoltaic device 12 to protect the photovoltaic device 12 from contamination and from the environment as well as adhere the substrates 14, 16 together.

An edge frame 28 is located near an edge or periphery of the solar module 10 between the first substrate 14 and the second substrate 16. The edge frame 28 may have various widths. The edge frame 28 is sealed to the laminate layer 26 using an adhesive sealant, such as a hot-melt butyl.

A potting compound 30 is disposed within the opening 22 of the substrate 16 in order to seal the lead lines 20 and the opening 22. The potting compound 30 has low moisture and vapor transmission (MVT), low conductivity, as well as good leveling and flow properties at application temperatures. The potting compound 30 has a viscosity that allows the potting compound 30 to be easily applied within the opening 22. The potting compound 30 malleability also allows the potting compound 30 to be compliant such that movement of the lead lines 20 does not break the seal of the potting compound 30. In addition, the potting compound 30 is disposed within the junction box 24 to seal any openings and protect the internal connections from moisture penetration.

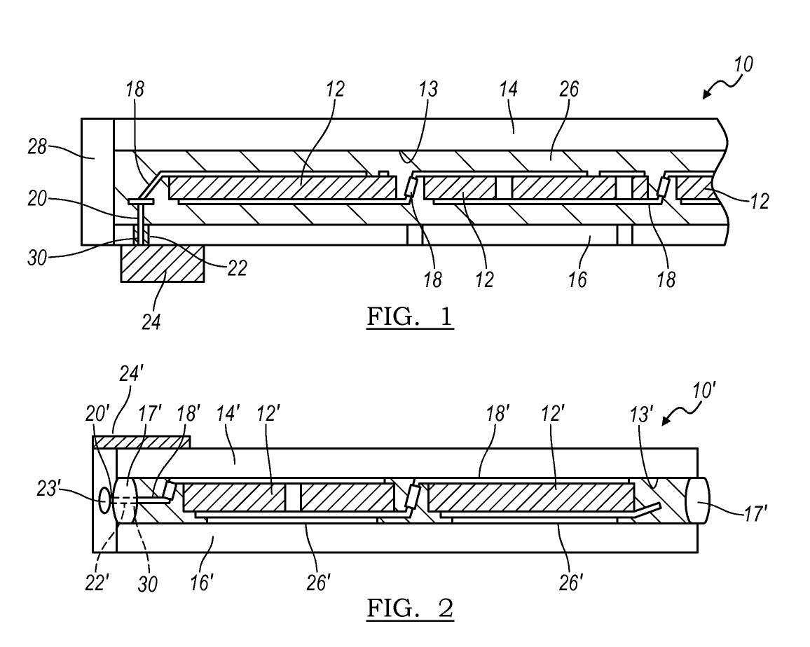

Turning to FIG. 2, an alternate solar module using the potting compound 30 is indicated by reference number 10′. The solar module 10′ includes a plurality of photovoltaic cells 12′ located within a chamber 13′ defined by a first substrate 14′ and a second substrate 16′. It should be appreciated that any number of photovoltaic cells 12′ may be employed in the solar module 10′. An edge seal 17′ is disposed around a periphery or edge of the solar module 10′ between the first substrate 14′ and the second substrate 16′. The edge seal 17′ is operable to adhere the substrates 14′ and 16′ together as well as seal the chamber 13′. The chamber 13′ may be filled with an inert gas.

The photovoltaic cells 12′ are operable to generate an electrical current from sunlight striking the photovoltaic cells 12′. Accordingly, the photovoltaic cells 12′ may take various forms without departing from the scope of the present invention. For example, the photovoltaic cells 12′ may be a thin film cell with a layer of cadmium telluride (Cd—Te), amorphous silicon, or copper-indium-diselenide (CuInSe₂). Alternatively, the photovoltaic cells 12′ may be a crystalline silicon wafer embedded in a laminating film or gallium arsenide deposited on germanium or another substrate. Other types of photovoltaic cells 12′ that may be employed include organic semiconductor cells having conjugate polymers as well as dye-sensitized metal oxides including wet metal oxides and solid metal oxides. The photovoltaic cells 12′ may be either rigid or flexible. The photovoltaic cells 12′ are linked either in series or in parallel or combinations thereof. The current generated by the photovoltaic cells 12′ are communicated via bus bars or other conductive materials or layers 18′ to wires or lead lines 20′ that exit the solar module 10′ via an opening 22′ in the edge seal 17′. The lead lines 20′ communicate with an external connector 23′. The external connector 23′ communicates with a junction box 24′ in order to distribute the electrical current generated by the solar module 10′ to a power circuit. The junction box 24′ may be located on a side or top of the solar module 10′.

The first substrate 14′, or front panel, is formed from a material operable to allow wavelengths of sunlight to pass therethrough. For example, the first substrate 14′ is glass or a plastic film such as polyvinylfluoride. The second substrate 16′, or back panel, is selected to provide additional strength to the solar module 10′. For example, the second substrate 16 is a plastic such as glass or fluorinated ethylene-propylene copolymer (FEP), poly(ethylene-co-tetrafluoroethylene) (ETFE), polyvinylidene fluoride (PVDF), polyvinyl fluoride (PVF), poly(tetrafluoroethylene) (PTFE) and combinations of these with other polymeric materials.

The photovoltaic cells 12′ are adhered to the back substrate 16′ with an adhesive strip or layer 26′. The adhesive strip 26′ may take various forms without departing from the scope of the present invention.

The potting compound 30 is disposed within the opening 22′ of the edge seal 17′ in order to seal the lead lines 20′ and the opening 22′. The potting compound 30 has low moisture and vapor transmission (MVT), low conductivity, as well as a particular viscosity. In addition, the potting compound 30 can be disposed within the junction box 24 to seal any openings and to protect the internal connections of the junction box 24 from moisture penetration.

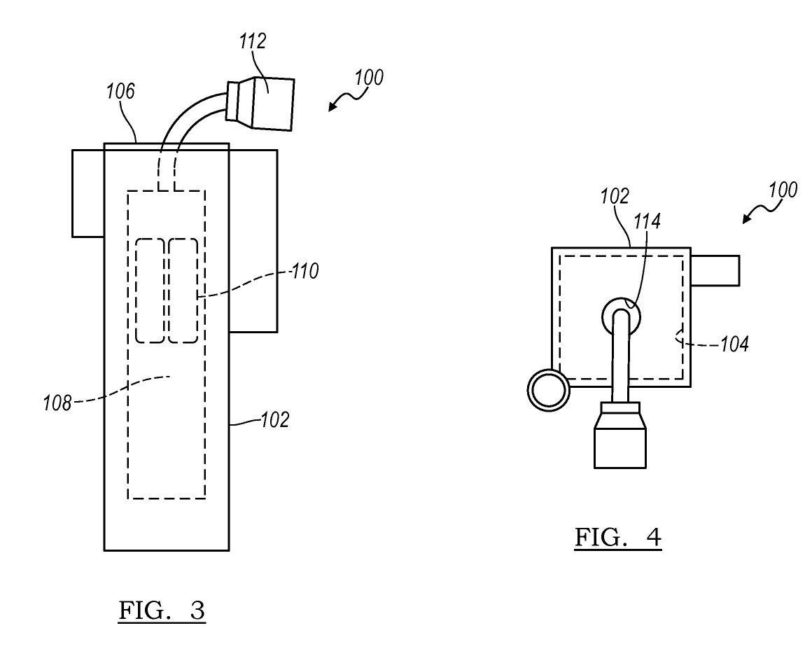

Turning now to FIGS. 3 and 4, another example of a solid state device employing the potting compound 30 of the present invention is generally indicated by reference number 100. The solid state device 100 is, in the example provided, a water meter that is capable of being disposed underground below the frost line and is operable to electronically communicate with a receiver in order to measure water usage at a home or business. The device 100 generally includes a housing 102 that defines an inner cavity 104. The housing 100 may take various shapes and sizes and have any number of connectors, flanges, protrusions, support members, and reinforcement ribs that are specific to the particular operating conditions and design requirements of the device 100. The housing 102 includes a cap or other component 106 that covers the cavity 104.

A solid state circuit board 108 is located within the cavity 104 of the housing 102. The solid state circuit board 108 is built from solid materials and in which the electrons, or other charge carriers, are confined entirely within the solid material. In the example provided, the solid state circuit board 108 includes a power source 110, such as a battery pack, and a connector 112 interconnected with a plurality of circuits (not shown). The connector 112 extends out of the housing 102 through an opening 114 in the cap 106.

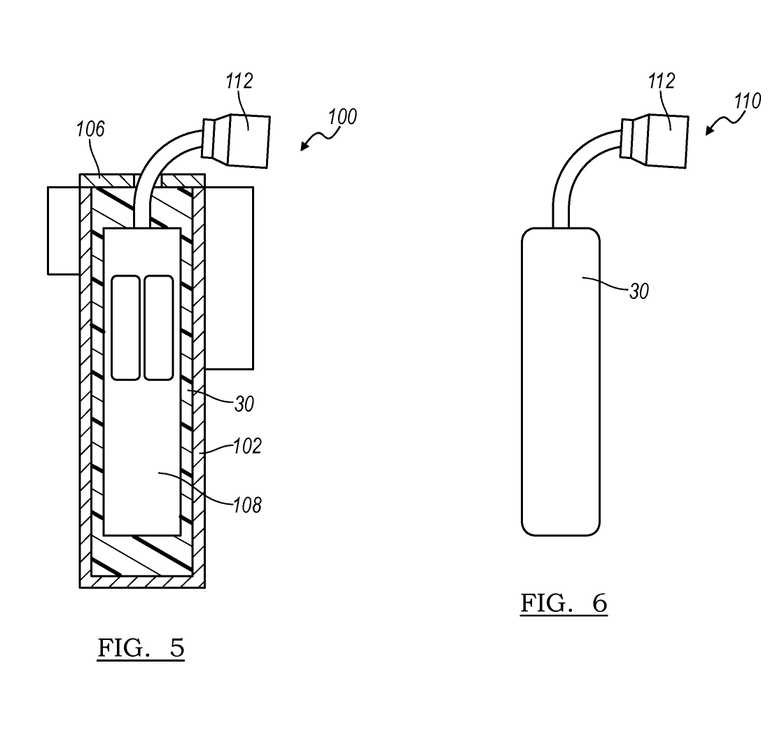

In order to protect the solid state device 100 from moisture penetration, the potting compound 30 is applied to the solid state device 100 in any manner such that the solid state circuit board 108 is encapsulated. For example, with reference to FIG. 5, the solid state circuit board 108 is disposed within the cavity 104 of the housing 102 and the cavity 104 is then filled with the potting compound 30. The potting compound 30 completely covers and encapsulates the solid state circuit board 108. In an alternate example, shown in FIG. 6, the solid state circuit board 108 is covered with the potting compound 30 prior to placement within the housing 102. Again, the potting compound 30 completely covers and encapsulates the solid state circuit board 108. The potting compound 30 may be dipped, sprayed, or otherwise applied to the solid state circuit board 108 without departing from the scope of the present invention. The potting compound 30 may be applied at a temperature range from about 100° C. to about 200° C.

In addition to the examples provided above, the potting compound 30 may be used with any moisture sensitive device, such as tire pressure sensors, window seals, wires seals, etc.

The composition of the potting compound 30 includes olefinic polymers, polyethylene wax, a silane, an antioxidant, and fillers. These components are balanced to produce a potting compound having desirable properties including Moisture Vapor Transmission Rate (MVTR), good flow at temperature of application, and no sag at use temperatures (e.g., 125° C.).

Moisture Vapor Transmission Rate is measured by a MOCON tester using ASTM F-1249. The MVTR of the composition of the potting compound 30 is preferably less than 0.3 g/m² per 24 hours.

For some embodiments, such as, for example for use in solar modules, the Boeing sag was measured using ASTM D2202-73 with a Boeing sag test fixture. The Boeing sag of the potting compound 30 is preferably less than about 0.15 inch at 125° C. The viscosity was measured using ASTM D2452, using a Brookfield viscometer. The composition of the potting compound 30 has a viscosity at 300° F. of approximately 50,000 cps.

In order that the invention may be more readily understood, reference is made to the following examples which are intended to illustrate the invention, but not limit the scope thereof:

### EXAMPLE 1

| | | | Amt. in % by | |
|---|---|---|---|---|
| | | | Total Weight | |
| Exemplary | Manu- | | Lower | Upper |
| Trade Name | facturer | Chemical Name | Limit | Limit |
| Oppanol B10 | BASF | Polyisobutylene | 40% | 100% |
| Irganox 1010 | Ciba | Tetrakis[methylene(3,5- | 0% | 4% |
| | | di-tert-butylhydroxyhydro- | | |
| | | cinnanamte)]methane | | |
| PE100 | Westco | Polyethylene wax | 2% | 30% |
| H-300 | INEOS | Polybutene | 0% | 50% |
| Nerox 2500 | Evonik- | Carbon black | 0% | 10% |
| | Deggussa | | | |
| SCA-603 | | 3-(2-aminoethyl)- | 0% | 10% |
| | | aminopropyltri- | | |
| | | methoxysilane | | |

### EXAMPLE 2

| | | | Amt. in % by | |
|---|---|---|---|---|
| | | | Total Weight | |
| Exemplary | Manu- | | Lower | Upper |
| Trade Name | facturer | Chemical Name | Limit | Limit |
| Oppanol B10 | BASF | Polyisobutylene | 60% | 95% |
| Irganox 1010 | Ciba | Tetrakis[methylene(3,5- | 0% | 2% |
| | | di-tert-butylhydroxyhydro- | | |
| | | cinnanamte)]methane | | |
| PE100 | Westco | Polyethylene wax | 8% | 20% |
| H-300 | INEOS | Polybutene | 0% | 30% |
| Nerox 2500 | Evonik- | Carbon black | 0% | 5% |
| | Deggussa | | | |
| SCA-603 | | 3-(2-aminoethyl)- | 0% | 5% |
| | | aminopropyltri- | | |
| | | methoxysilane | | |

### EXAMPLE 3

| | | | Amt. in % by | |
|---|---|---|---|---|
| | | | Total Weight | |
| Exemplary | Manu- | | Lower | Upper |
| Trade Name | facturer | Chemical Name | Limit | Limit |
| Opanol B10 | BASF | Polyisobutylene | 60% | 80% |
| Irganox 1010 | Ciba | Tetrakis[methylene(3,5- | 0% | 1% |
| | | di-tert-butylhydroxyhydro- | | |
| | | cinnanamte)]methane | | |
| PE100 | Westco | Polyethylene wax | 10% | 16% |
| H-300 | INEOS | Polybutene | 4% | 28% |
| Nerox 2500 | Evonik- | Carbon black | 0% | 3% |
| | Deggussa | | | |
| SCA-603 | | 3-(2-aminoethyl)- | 0% | 3% |
| | | aminopropyltri- | | |
| | | methoxysilane | | |

### EXAMPLE 4

| Exemplary | | | Amt. in % |
|---|---|---|---|
| Trade Name | Manufacturer | Chemical Name | by Total Weight |
| Oppanol B10 | BASF | Polyisobutylene | 58% |
| Irganox 1010 | BASF | Tetrakis[methylene(3,5-di-tert- | 0.24% |
| | | butylhydroxyhydrocinnanamte)]methane | |
| Vestoplast 308 | Evonik | Amorphous Polyalphaolefin | 14.8% |
| | | (APAO) | |
| Printex 30 | Evonik | Carbon Black | 2% |
| Tinuvin 152 | BASF | Hindered Amine Light Stabilizer | 0.3% |
| Polywax 2000 | Baker Hughes | Polyethylene | 11.9% |
| Hubercarb G8 | Evonik- | Calcium Carbonate | 0.12% |
| | Deggussa | | |
| SCA-603 | Dow Corning | 3-(2-aminoethyl)- | 0.5% |
| | | aminopropyltrimethoxysilane | |
| Quicklime | Mississippi | CaO | 8% |
| | Lime | | |
| Vestoplast 206 | Evonik | Silane grafted APAO | 10% |

### EXAMPLE 5

| | | | Amt. in % |
|---|---|---|---|
| Exemplary | | | by Total |
| Trade Name | Manufacturer | Chemical Name | Weight |
| Oppanol | BASF | Polyisobutylene | 71.2% |
| B10 | | | |
| Irganox | Ciba | Tetrakis[methylene(3,5-di- | 0.24% |
| 1010 | | tert-butylhydroxyhydro- | |
| | | cinnanamte)]methane | |
| PE100 | Westco | Polyethylene wax | 14.8% |
| H-300 | INEOS | Polybutene | 11.9% |
| Nerox 2500 | Evonik- | Carbon black | 0.12% |
| | Deggussa | | |
| SCA-603 | | 3-(2-aminoethyl)- | 1.8% |
| | | aminopropyltrimethoxysilane | |

### EXAMPLE 6

In this example, viscosity (cp) was measured at 175° C., as per ASTM D3236, and Boeing Sag (inch) was measured at 125° C., as per ASTM D2202-73:

| Ingredient | A | B | C | D | E | F | G | H | I | J | Sag | Visc. |
|---|---|---|---|---|---|---|---|---|---|---|---|---|
| Polyisobutylene | 62% | 55% | 60% | 58% | 62% | 59% | 62% | 59% | 62% | 59% | 1.5″ | 73440 |
| APAO | 10% | 12% | 8% | 10% | 9% | 12% | 12% | 12% | 8% | 11% | 0.1″ | 54550 |
| Antioxidant | 0.2% | 0.2% | 0.2% | 0.2% | 0.2% | 0.2% | 0.2% | 0.2% | 0.2% | 0.2% | 0.6″ | 50200 |
| Carbon Black | 2% | 2% | 2% | 2% | 2% | 2% | 2% | 2% | 2% | 2% | 0 | 55270 |
| HALS | 0.3% | 0.3% | 0.3% | 0.3% | 0.3% | 0.3% | 0.3% | 0.3% | 0.3% | 0.3% | 0 | 54330 |
| Polyethylene wax | 4% | 8% | 8% | 7% | 7% | 6% | 5% | 4% | 5% | 8% | 0 | 59810 |
| Calcium Carbonate | 5% | 5% | 5% | 5% | 5% | 5% | 5% | 5% | 5% | 5% | 0 | 63300 |
| Calcium Oxide | 8% | 8% | 8% | 8% | 8% | 8% | 8% | 8% | 8% | 8% | 1.8″ | 66100 |
| Silane modified APAO | 9% | 10% | 9% | 10% | 7% | 8% | 6% | 10% | 10% | 6% | 2.2″ | 74270 |
| Silane | 0.5% | 0.5% | 0.5% | 0.5% | 0.5% | 0.5% | 0.5% | 0.5% | 0.5% | 0.5% | 2.3″ | 54400 |

where:
A = Polyisobutylene (Oppanol B10 from BASF)
B = APAO or Amorphous polyalphaolefin (Vestoplast 308, 508 from Evonik)
C = Antioxidant (Irganox 1010 from BASF)
D = Carbon Black (Nerox 2500, Printex 30 from Evonik)
E = Hindered Amine Light Stabilizer (Tinuvin 292, 152 from BASF)
F = Polyethylene wax (Polywax 2000, 3000 from Baker Hughes)
G = Calcium carbonate (Hubercarb G8, G35 from J. M. Huber)
H = Calcium Oxide (Quicklime from Mississippi Lime)
I = Silane modified APAO (Vestoplast 206, Vestoplast 2403 from Evonik)
J = Silane (SCA-603 from Dow Corning)

### EXAMPLE 7

In this example, the following formulations were applied between two test substrates and their normal tensile strength was determined with an Instron device using a cross pluck testing fixture (as per ASTM C907).

| Ingredients | K | L | M |
|---|---|---|---|
| Polyisobutylene | 54% | 58% | 58% |
| APAO | 12% | 10% | 10% |
| Antioxidant | 0.2% | 0.2% | 0.2% |
| Carbon Black | 2% | 2% | 2% |
| HALS | 0.3% | 0.3% | 0.3% |
| Polyethylene wax | 8% | 8% | 8% |
| Calcium Carbonate | 5% | 4% | 4% |
| Calcium Oxide | 8% | 8% | 8% |
| Silane modified APAO | 10% | 10% | 0% |
| Non-silane modified APAO | 0% | 0% | 10% |
| Silane | 2% | 1% | 1% |
| Boeing Sag | 0.4″ | 0″ | 0″ |
| Viscosity (in cps) | 37170 | 47000 | 51150 |
| Surface Resistivity (in Ω/square) | 5.1 × 10¹⁵ | 1.9 × 10¹⁶ | 5.2 × 10¹⁵ |
| Volume Resistivity (in Ω · cm) | 7.3 × 10¹⁶ | 7.0 × 10¹⁶ | 7.7 × 10¹⁶ |

The tests were run after samples were exposed to conditions as per UL 1703 under the following conditions: 24 hours at room temperature; Damp heat=85° C., 85% humidity for 1000 hours; Thermal cycling=200 cycles (−40° C. to 85° C.); and Humidity freeze=10 cycles (−40° C. to 85° C. with 85% humidity). The following table shows the results of the tests:

| Exposure Test Results | K | L | M |
|---|---|---|---|
| Glass/glass substrates | | | |
| (tensile strength in psi) | | | |
| 24 hours at room temp | 93 (cf) | 131 (cf) | 98 (cf) |
| 1000 h damp heat | 115 (cf) | 123 (cf) | 116 (cf) |
| Thermal cycling | 115 (cf) | 117 (af/cf) | 105 (cf) |
| Humidity freeze | 80 (cf) | 107 (cf) | 69 (cf/af) |
| PPO/glass substrates | | | |
| (tensile strength in psi) | | | |
| 24 hours at room temp | 42 (cf) | 41 (cf) | 42 (cf) |
| 1000 h damp heat | 36 (cf) | 44 (cf) | 30 (cf) |
| Thermal cycling | 34 (cf) | 46 (cf) | 37 (cf) |
| Humidity freeze | 30 (cf) | 32 (cf) | 27 (cf) |

where PPO = Noryl SE1-GF from SABIC, cf = cohesive failure, and af = adhesive failure.

In accordance with the principles of the present invention, the olefinic polymers may be selected from a group including, but not limited to, the following: polyisobutylene and polybutene, polyethylene, polypropylene, polybutene, polyisobutene, butyl rubber (polyisobutene-isoprene), styrene block copolymers (in modified form as well), and combinations thereof. Other polyolefins or fluorinated polymers may be employed without departing from the scope of the present invention. In a preferred embodiment, the olefinic polymers include polyisobutylene and polybutene.

The polyethylene wax may be replaced with any wax with a softening/melting point from about 50° C. to about 200° C.

The antioxidant may be selected from a group including, but not limited to, the following: Tetrakis [methylene(3,5-di-tert-butylhydroxyhydrocinnanamte)]methane, hindered phenols, hindered amines, thioethers, mercapto compounds, phosphorous esters, benzotriazoles, benzophenones, antiozonants, and combinations thereof. In a preferred embodiment, the antioxidant includes Tetrakis [methylene(3,5-di-tert-butylhydroxyhydrocinnanamte)]methane.

The silane may be selected from a group including, but not limited to, the following: 3-(2-aminoethyl)-aminopropyltrimethoxysilane, DFDA-5451NT (silane grafted PE from Dow Chemical), DFDA-5481 NT (moisture curing catalyst from Dow Chemical), amorphous poly alpha olefins (such as, for example, Vestoplast 206, Vestoplast 2412), alkoxy silanes, amino silanes, and combinations thereof. In a preferred embodiment, the silane includes 3-(2-aminoethyl)-aminopropyltrimethoxysilane.

The carbon black is used for pigmentation and can be changed or excluded. For example, titanium dioxide may be used as a pigment without departing from the scope of the present invention.

In addition, a water scavenger such as Mississippi Lime or desiccant such as molecular sieves, or anhydrous inorganic salts, may be included without departing from the present invention.

The description of the invention is merely exemplary in nature and variations that do not depart from the gist of the invention are intended to be within the scope of the invention. Such variations are not to be regarded as a departure from the spirit and scope of the invention.

1. A moisture barrier potting compound comprising:
a) at least one olefinic polymer included in an amount from about 40% to about 95% by weight of the total compound;
b) at least one silane included in an amount from about 0.1% to about 15% by weight of the total compound;
c) at least one wax included in an amount from about 2% to about 30% by weight of total compound;
d) at least one antioxidant included in an amount from about 0.1% to about 4% by weight of the total compound; and
e) at least one filler included in an amount from about 0.1% to about 20% by weight of the total compound.

2. The potting compound of claim 1, wherein the at least one olefinic polymer is selected from the group consisting of polyisobutylene, polybutene, polyethylene, polypropylene, polybutene, polyisobutene, butyl rubber (polyisobutene-isoprene), styrene block copolymers, and combinations thereof.

3. The potting compound of claim 2, wherein the at least one olefinic polymer is a polyisobutylene, a polybutene, or a combination thereof.

4. The potting compound of claim 1, wherein the at least one olefinic polymer is a polyolefin, fluorinated polymer, or a combination thereof.

5. The potting compound of claim 1, wherein the at least one wax is a polyethylene wax.

6. The potting compound of claim 1, wherein the at least one wax has a softening/melting point from about 50° C. to about 200° C.

7. The potting compound of claim 1, wherein the at least one silane is selected from the group consisting of 3-(2-aminoethyl)-aminopropyltrimethoxysilane, DFDA-5451NT (silane grafted PE from Dow Chemical), DFDA-5481 NT (moisture curing catalyst from Dow Chemical), amorphous poly alpha olefins (such as, for example, Vestoplast 206, Vestoplast 2412), alkoxy silanes, amino silanes, and combinations thereof.

8. The potting compound of claim 1, wherein the at least one silane is 3-(2-aminoethyl)-aminopropyltrimethoxysilane.

9. The potting compound of claim 1, wherein the antioxidant is selected from the group consisting of Tetrakis [methylene(3,5-di-tert-butylhydroxyhydrocinnanamte)]methane, hindered phenols, hindered amines, thioethers, mercapto compounds, phosphorous esters, benzotriazoles, benzophenones, antiozonants, and combinations thereof.

10. The potting compound of claim 1, wherein the at least one antioxidant is Tetrakis [methylene(3,5-di-tert-butylhydroxyhydrocinnanamte)]methane.

11. The potting compound of claim 1, wherein the at least one filler is selected from the group consisting of titanium dioxide, calcium carbonate, fumed silica, carbon black, and combinations thereof.

12. The potting compound of claim 1, wherein the at least one filler is carbon black.

13. The potting compound of claim 1 further comprising at least one of a desiccant and water scavenger included in an amount from about 0.1% to about 10%, wherein the at least one of a desiccant and water scavenger is selected from the group consisting of Mississippi lime, molecular sieves, or anhydrous inorganic salts.

14. The potting compound of claim 1, wherein the potting compound has a moisture vapor transmission rate of less than about 0.3 g/m2 per 24 hours.

15. A solar module comprising:
a first substrate;
a second substrate;
at least one photovoltaic cell disposed between the first and the second substrates, current generated by the at least one photovoltaic cell being communicated to lead lines that exit through an opening in the solar module; and
a potting compound disposed within the opening of the solar module to seal the lead lines and the opening, wherein the potting compound includes:
at least one olefinic polymer;
at least one silane;
at least one wax;
at least one antioxidant; and
at least one filler.

16. The solar module of claim 15, wherein the at least one olefinic polymer is included in an amount from about 40% to about 95% by weight of the total compound, the at least one silane is included in an amount from about 0.1% to about 15% by weight of the total compound, the at least one wax is included in an amount from about 2% to about 30% by weight of total compound, the at least one antioxidant is included in an amount from about 0.1% to about 4% by weight of the total compound, and the at least one filler is included in an amount from about 0.1% to about 20% by weight of the total compound.

17. The solar module of claim 15, wherein the opening in the solar module is an opening in either the first substrate or the second substrate.

18. The solar module of claim 15 further comprising an edge seal disposed around the periphery of the solar module between the first substrate and the second substrate to form a moisture vapor barrier to hinder moisture vapor from reaching the at least one photovoltaic cell, wherein the opening in the solar module is an opening in the edge seal.

19. A solid state device comprising:
a housing that defines an inner cavity;
a circuit board located within the housing; and
a potting compound that encapsulates the circuit board to form a moisture barrier to protect the circuit board from moisture penetration, wherein the potting compound includes:
at least one olefinic polymer;
at least one silane;
at least one wax;
at least one antioxidant; and
at least one filler.

20. The solid state device of claim 19, wherein the at least one olefinic polymer is included in an amount from about 40% to about 95% by weight of the total compound, the at least one silane is included in an amount from about 0.1% to about 10% by weight of the total compound, the at least one wax is included in an amount from about 2% to about 30% by weight of total compound, the at least one antioxidant is included in an amount from about 0.1% to about 4% by weight of the total compound, and the at least one filler is included in an amount from about 0.1% to about 10% by weight of the total compound.
